(19) United States
(12) Patent Application Publication
(10) Pub. No.: US 2025/0204028 A1
(43) Pub. Date: Jun. 19, 2025

(54) SEMICONDUCTOR DEVICE AND METHOD FOR FORMING THE SAME

(71) Applicant: Powerchip Semiconductor Manufacturing Corporation, Hsinchu (TW)

(72) Inventor: Meng-Han Lin, Hsinchu City (TW)

(73) Assignee: Powerchip Semiconductor Manufacturing Corporation, Hsinchu (TW)

(21) Appl. No.: 18/406,220

(22) Filed: Jan. 8, 2024

(30) Foreign Application Priority Data
Dec. 15, 2023 (TW) 112148958

(51) Int. Cl. H01L 27/088; H01L 21/8234; H01L 21/8238; H01L 27/092

(52) U.S. Cl. CPC H10D 84/83; H10D 84/0128; H10D 84/0142; H10D 84/0144; H10D 84/0167; H10D 84/0179; H10D 84/0181; H10D 84/038; H10D 84/85

(57) ABSTRACT

The present disclosure provides a semiconductor device and a method for forming the same. The semiconductor device includes a substrate including a first and a second active regions defined by a device isolation structure and first and second elements respectively disposed in the first and second active regions and respectively including a first and a second gate structures. The first gate structure includes a first gate electrode and a first gate dielectric layer between the substrate and the first gate electrode. The second gate structure includes a second gate electrode and a second gate dielectric layer between the substrate and the second gate electrode. The first gate dielectric layer includes a first portion in contact with the substrate and a second portion protruding from the first portion in a vertical direction, and the thickness of the first portion is smaller than that of the second gate dielectric layer.

### CROSS-REFERENCE TO RELATED APPLICATION

This application claims the priority benefit of Taiwan application serial no. 112148958, filed on Dec. 15, 2023. The entirety of the above-mentioned patent application is hereby incorporated by reference herein and made a part of this specification.

### BACKGROUND

### Technical Field

The present invention is related to a semiconductor device and a method for forming the same.

### Description of Related Art

Power semiconductor components such as a power metal oxide semiconductor field effect transistor (MOSFET) are power components commonly used in analog circuits and/or digital circuits, and it can be divided into planar power semiconductor components and vertical power semiconductor components according to the direction of the current flow. In the planar power semiconductor components, increasing the distance from the gate to the drain or the thickness of the gate dielectric layer is a common means to increase the operating voltage of the power semiconductor components.

However, in order to meet the users' various needs for electronic components, it is necessary to integrate the power components and/or the logic components having different operating voltages. However, there is a trade-off between the device performance and the complexity, feasibility or stability of the manufacturing processes when these power and/or logic components are integrated together. For example, a power component with an operating voltage of 32V (hereinafter referred to as a first power component) and a power component with an operating voltage of 20V (hereinafter referred to as a second power component) are designed to have gate dielectric layers with different thicknesses. However, considering the complexity, feasibility or stability of the manufacturing process, the gate dielectric layers of the first and second power elements are usually formed to have the same thickness, and therefore the performance of one of the first and second power elements will be sacrificed.

As such, researchers in the field are still devoted to integrate the power devices and/or the logic devices having different operating voltages under the condition where the complexity, stability or feasibility of the manufacturing processes are acceptable or good and the device performances are not sacrificed as well.

### SUMMARY

The present invention provides a semiconductor device and a method of forming the semiconductor device in which a first gate dielectric layer of a first element is designed to include a first portion in contact with a substrate and having a thickness smaller than a thickness of a second gate dielectric layer of a second element and a second portion protruding from the first portion and having a top surface at a level height identical to a top surface of the second gate dielectric layer. As such, the semiconductor device is capable of integrating the power devices and/or the logic devices (e.g., the first and second elements) having different operating voltages under the condition where the stability of the manufacturing processes are good and the device performances are not sacrificed as well.

An embodiment of the present application provides a semiconductor device including a substrate, a first element, and a second element. The substrate includes a first active region and a second active region defined by an element isolation structure. The first element is disposed in the first active region and includes a first gate structure. The first gate structure includes a first gate electrode and a first gate dielectric layer disposed between the substrate and the first gate electrode. The second element is disposed in the second active region and includes a second gate structure. The second gate structure includes a second gate electrode and a second gate dielectric layer disposed between the substrate and the second gate electrode. The first gate dielectric layer includes a first portion in contact with the substrate and a second portion protruding from the first portion in a vertical direction. A thickness of the first portion in the vertical direction is smaller than a thickness of the second gate dielectric layer in the vertical direction, and a top surface of the second portion is at a level height identical to a top surface of the second gate dielectric layer. In some embodiments, a top surface of the first gate electrode includes a recess recessed

toward the substrate.

In some embodiments, the top surface of the first gate electrode in a region other than the recess is at a level height identical to a top surface of the second gate electrode.

In some embodiments, wherein a horizontal area of the second element is greater than a horizontal area of the first element.

In some embodiments, the first element includes a first isolation structure disposed in the first active region. The first isolation structure defines regions with the element isolation structure where first source/drains of the first element are disposed and defines a region under the first gate structure where a first doped region of the first element is disposed. The second portion of the first gate dielectric layer overlaps the first isolation structure in the vertical direction.

In some embodiments, the first element includes a first gate spacer disposed on a sidewall of the first gate electrode, and the second portion of the first gate dielectric layer is disposed between the first gate electrode and the first gate spacer in a horizontal direction.

In some embodiments, the second element includes a second gate spacer disposed on a sidewall of the second gate electrode, and the first gate spacer and the second gate spacer are respectively disposed on the first isolation structure and on the second isolation structure.

In some embodiments, the semiconductor device further includes a third element disposed in a third active region defined by the element isolation structure and different from the first active region and the second active region and including a third gate structure. The third gate structure includes a third gate electrode, a third gate dielectric layer disposed between the substrate and the third gate electrode, and a third gate spacer disposed on a sidewall of the third gate electrode. The third gate spacer is in contact with the substrate.

In some embodiments, a horizontal area of the third element is smaller than a horizontal area of the first element and a horizontal area of the second element.

In some embodiments, the second element includes a second isolation structure disposed in the second active region. The second isolation structure defines regions with the element isolation structure where second source/drains of the second element are disposed and defines a region under the second gate structure where a second doped region of the second element is disposed. A width of the second doped region in a horizontal direction is greater than a width of the first doped region in the horizontal direction.

An embodiment of the present application provides a method of forming the semiconductor device, which includes following steps: forming an element isolation structure defining a first active region and a second active region in a substrate; forming a dielectric material layer on the first active region and the second active region of the substrate; patterning a dielectric material layer on the first active region to form a first recess in the dielectric material layer on the first active region; forming a gate material layer on the dielectric material layer; and patterning the gate material layer and the dielectric material layer to form a first gate electrode and a first gate dielectric layer disposed between the substrate and the first gate electrode on the first active region and to form a second gate electrode and a second gate dielectric layer disposed between the substrate and the second gate electrode on the second active region. The first gate dielectric layer includes a first portion in contact with the substrate and a second portion protruding from the first portion in a vertical direction, a thickness of the first portion in the vertical direction is smaller than a thickness of the second gate dielectric layer in the vertical direction. A top surface of the second portion is formed at a level height identical to a top surface of the second gate dielectric layer.

In some embodiments, the method further includes: forming a first gate spacer and a second gate spacer on a sidewall of the first gate electrode and a sidewall of the second gate electrode, respectively. The second portion of the first gate dielectric layer is disposed between the first gate electrode and the first gate spacer in a horizontal direction.

In some embodiments, a top surface of the first gate electrode includes a second recess above the first recess and being recessed toward the substrate.

In some embodiments, the top surface of the first gate electrode in a region other than the second recess is formed at a level height identical to a top surface of the second gate electrode.

In some embodiments, the method further includes: forming a first isolation structure in the first active region to define regions with the element isolation structure where first source/drains are formed and a region under the first gate structure where a first doped region is formed. The second portion of the first gate dielectric layer overlaps the first isolation structure in the vertical direction.

In some embodiments, the method further includes: forming a second isolation structure in the second active region to define regions with the element isolation structure where second source/drains are formed and a region under the second gate structure where a second doped region is formed. A width of the second doped region in the horizontal direction is greater than a width of the first doped region in the horizontal direction.

In some embodiments, the element isolation structure defines a third active region in the substrate, and in a step of forming the first recess in the dielectric material layer on the first active region, a dielectric layer on the third active region is removed as well.

In some embodiments, in a step of patterning the gate material layer and the dielectric material layer, a third gate electrode and a third gate dielectric layer disposed between the substrate and the third gate electrode are formed in the third active region. In a step of forming the first gate spacer and the second gate spacer, a third gate spacer is formed on a sidewall of the third gate electrode, and the third gate spacer is in contact with the substrate.

Based on the above, in the aforementioned semiconductor device and method of forming the same, the first gate dielectric layer of the first element is designed to include the first portion in contact with the substrate and having the thickness smaller than the thickness of the second gate dielectric layer of the second element and the second portion protruding from the first portion and having the top surface at the level height identical to the top surface of the second gate dielectric layer. As such, the semiconductor device is capable of integrating the power devices and/or the logic devices (e.g., the first and second elements) having different operating voltages under the condition where the stability of the manufacturing processes are good and the device performances are not sacrificed as well.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 to FIG. 10 is schematic cross-section views illustrating a method of forming a semiconductor device in an embodiment of the invention.

FIG. 11 is a schematic cross-section view illustrating a first element in an embodiment of the invention.

FIG. 12 is a schematic cross-section view illustrating a first element in another embodiment of the invention.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The invention will be described more comprehensively below with reference to the drawings for the embodiments. However, the invention may also be implemented in different forms rather than being limited by the embodiments described in the invention. Thicknesses of layer and region in the drawings are enlarged for clarity. The same reference numbers are used in the drawings and the description to indicate the same or like parts, which are not repeated in the following embodiments.

It will be understood that when an element is referred to as being “on” or “connected” to another element, it may be directly on or connected to the other element or intervening elements may be present. If an element is referred to as being “directly on” or “directly connected” to another element, there are no intervening elements present. As used herein, “connection” may refer to both physical and/or electrical connections, and “electrical connection” or “coupling” may refer to the presence of other elements between two elements. As used herein, “electrical connection” may refer to the concept including a physical connection (e.g., wired connection) and a physical disconnection (e.g., wireless connection).

As used herein, “about”, “approximately” or “substantially” includes the values as mentioned and the average values within the range of acceptable deviations that can be determined by those of ordinary skill in the art. Consider to the specific amount of errors related to the measurements (i.e., the limitations of the measurement system), the meaning of “about” may be, for example, referred to a value within one or more standard deviations of the value, or within ±30%, ±20%, ±10%, ±5%. Furthermore, the “about”, “approximate” or “substantially” used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

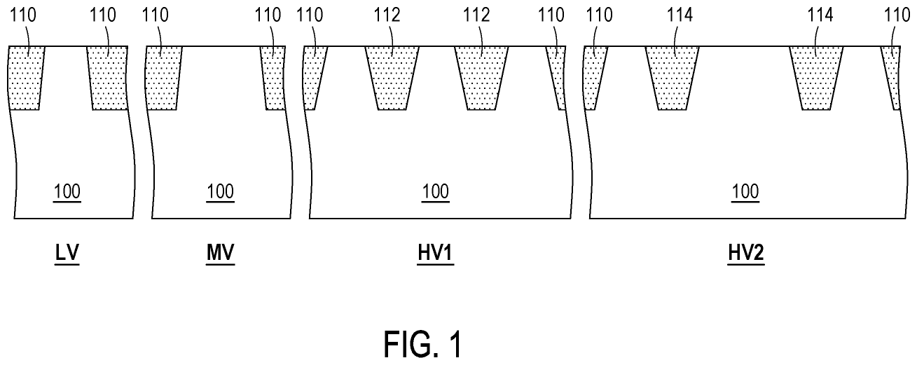

FIG. 1 to FIG. 10 is schematic cross-section views illustrating a method of forming a semiconductor device in an embodiment of the invention.

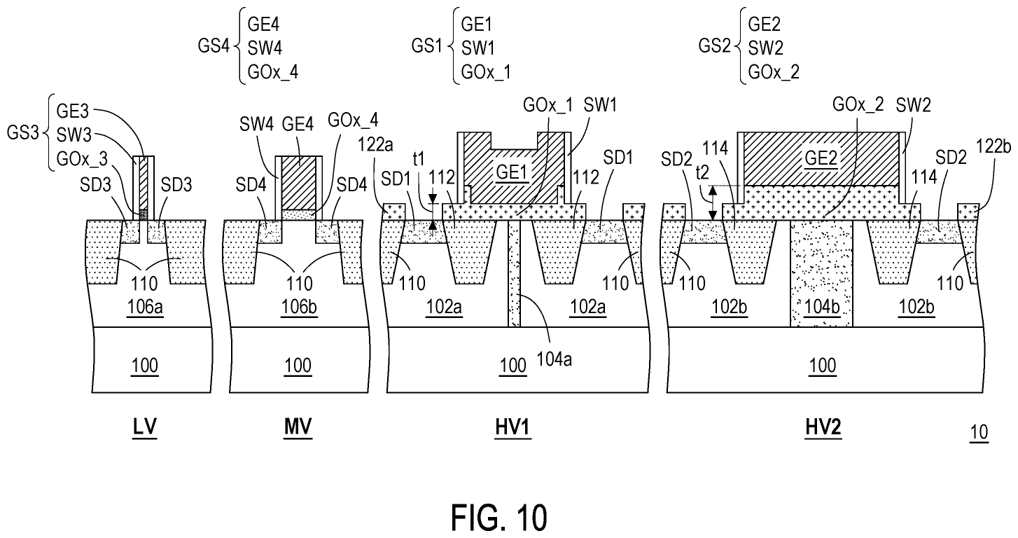

In some embodiments, a method of forming a semiconductor device (e.g., a semiconductor device 10 shown in FIG. 10) includes the following steps.

Firstly, referring to FIG. 1, an element isolation structure 110 defining a first active region HV1 and a second active region HV2 in a substrate 100 are formed. In some embodiments, the element isolation structure 110 may define a third active region LV and a fourth active region MV different from the first active region HV1 and the second active region HV2 in the substrate 100. In some embodiments, the first active region HV1 and the second active region HV2 may respectively be regions where high-voltage semiconductor elements are disposed; the third active region LV may be a region where low-voltage semiconductor elements are disposed; and the fourth active region MV may be a region where middle-voltage semiconductor elements are disposed. In some embodiments, the operating voltage (e.g., 20V) of the high-voltage semiconductor element disposed in the first active region HV1 may be lower than the operating voltage (e.g., 32V) of the high-voltage semiconductor element disposed in the second active region HV2. In some embodiments, the operating voltage of the low-voltage semiconductor element disposed in the third active region LV may be lower than the operating voltage of the middle-voltage semiconductor element disposed in the fourth active region MV. In some embodiments, the operating voltage of the high-voltage semiconductor element disposed in the first active region HV1 may be higher than the operating voltage of the middle-voltage semiconductor element disposed in the fourth active region MV.

The substrate 100 may include a semiconductor substrate or a semiconductor-on-insulator (SOI) substrate. The semiconductor materials in the semiconductor substrate or in the SOI substrate may include an element semiconductor, an alloy semiconductor, or a compound semiconductor. For example, the element semiconductor may include Si or Ge. The alloy semiconductor may include SiGe, SiGeC, or the like. The compound semiconductor may include SiC, III-V semiconductor materials, or II-VI semiconductor materials. The III-V semiconductor materials may include GaN, GaP, GaAs, AlN, AIP, AlAs, InN, InP, InAs, GaNP, GaNAs, GaPAs, AlNP, AlNAs, AlPAs, InNP, InNAs, InPAs, GaAINP, GaAINAs, GaAlPAs, GaInNP, GalnNAs, GalnPAs, InAINP, InAINAs, or InAlPAs. The II-VI semiconductor materials may include CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, or HgZnSTe. The semiconductor material may be doped with a dopant of a first conductivity type or a dopant of a second conductivity type complementary to the first conductivity type. For example, the first conductivity type may be p-type, whereas the second conductivity type may be n-type. In some embodiments, the substrate 100 may be doped with a p-type dopant. In some embodiments, the element isolation structure 110 may include silicon oxide.

In some embodiments, first isolation structures 112 may be formed in the first active region HV1, so as to define regions with the element isolation structures 110 where first source/drains are formed in the subsequent processes and a region between the first isolation structures 112 where a first doped region is formed in the subsequent processes. In some embodiments, second isolation structures 114 may be formed in the second active region HV2, so as to define regions with the element isolation structures 110 where second source/drains are formed in the subsequent processes and a region between the second isolation structures 114 where a second doped region is formed in the subsequent processes. In some embodiments, the first isolation structures 112 and the second isolation structures 114 may include silicon oxide.

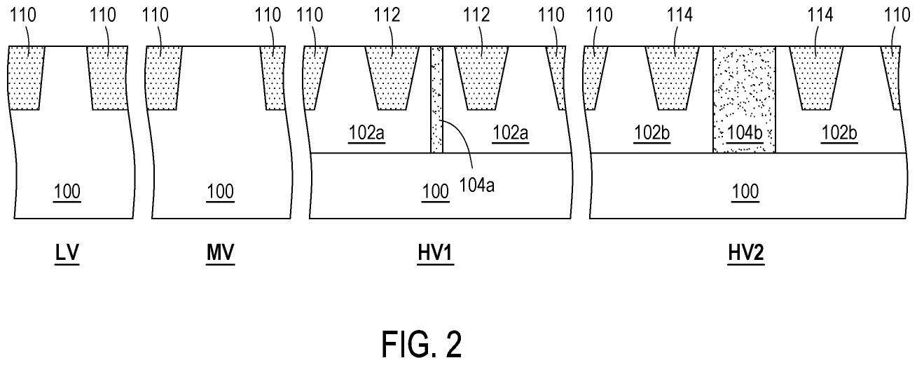

Then, referring to FIG. 2, a first well 102a and a second well 102b are respectively formed in the first active region HV1 and the second active region HV2 of the substrate 100. Next, a first doped region 104a is formed within the region in the first active region HV1 that is defined by the first isolation structures 112, and a second doped region 104b is formed within the region in the second active region HV2 that is defined by the second isolation structures 114. In some embodiments, the first doped region 104a may have a conductivity type different from the first well 102a, as such the first doped region 104a may divide the first well 102a into two parts. For example, the first well 102a may be doped with a dopant with the first conductivity type, whereas the first doped region 104a may be doped with a dopant with the second conductivity type. In some embodiments, the second doped region 104b may have a conductivity type different from the second well 102b, as such the second doped region 104b may divide the second well 102b into two parts. For example, the second well 102b may be doped with a dopant with the first conductivity type, whereas the second doped region 104b may be doped with a dopant with the second conductivity type. In some embodiments, a width of the second doped region 104b in the horizontal direction may be greater than a width of the first doped region 104a in the horizontal direction.

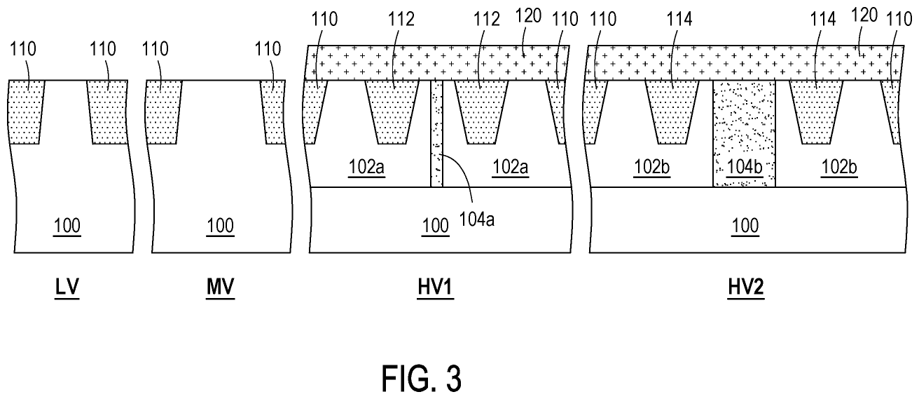

Next, referring to FIG. 3, a dielectric material layer 120 is formed on the first active region HV1 and the second active region HV2 of the substrate 100. In some embodiments, the dielectric material layer 120 covers the first active region HV1 and the second active region HV2 of the substrate 100 and exposes the third active region LV and the fourth active region MV of the substrate 100. In some embodiments, the dielectric material layer 120 may include materials suitable for the gate dielectric layers, such as silicon oxide.

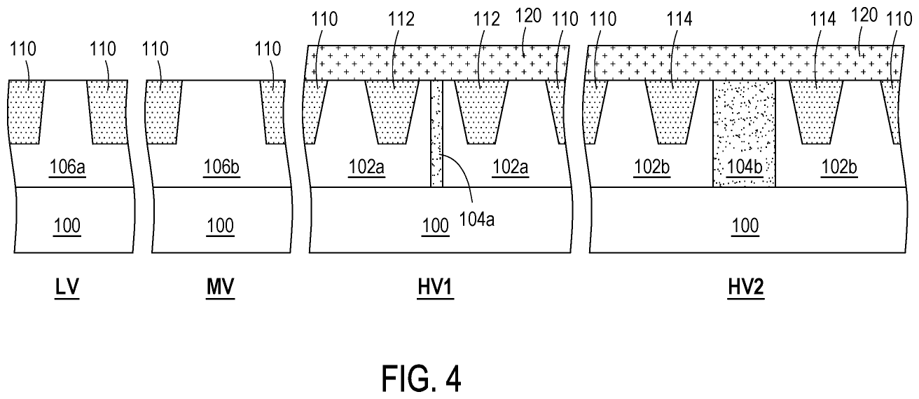

After that, referring to FIG. 4, a third well 106a and a fourth well 106b are respectively formed in the third active region LV and the fourth active region MV of the substrate 100. The third well 106a and the fourth well 106b may be each doped with a dopant with the first conductivity type or a dopant with the second conductivity type complementary to the first conductivity type.

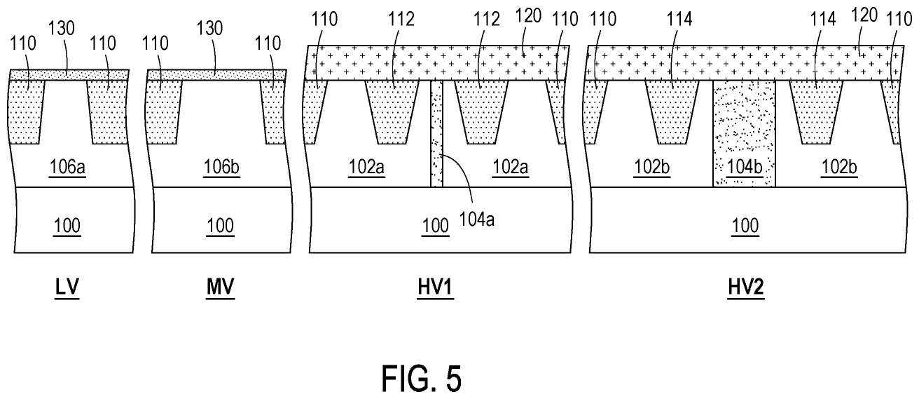

Then, referring to FIG. 5, a dielectric layer 130 may be formed on the third active region LV and the fourth active region MV of the substrate 100. In some embodiments, the dielectric layer 130 may include materials suitable for the gate dielectric layers, such as silicon oxide.

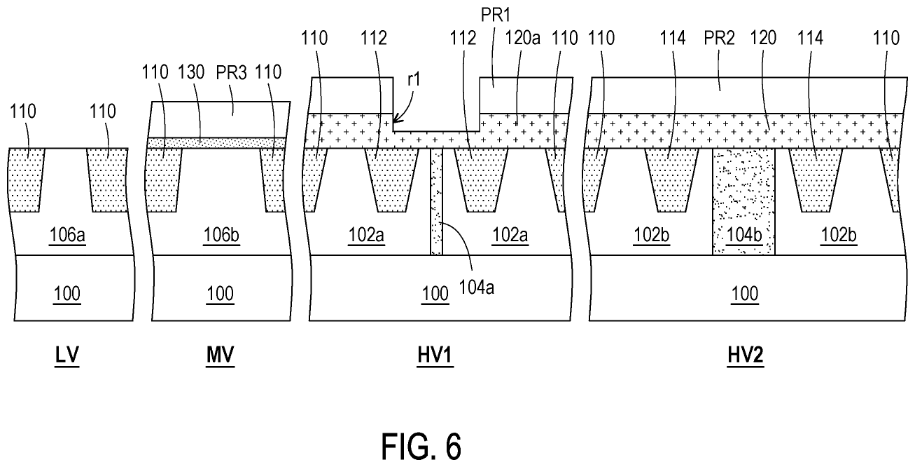

Next, referring to FIG. 5 and FIG. 6, the dielectric material layer 120 on the first active region HV1 is patterned to form a first recess r1 in the dielectric material layer 120 on the first active region HV1. In some embodiments, the first recess r1 may be formed by the following steps. Firstly, a mask layer is formed on the first active region HV1, the second active region HV2, and the fourth active region MV, wherein the mask layer includes a mask pattern PR1 formed on the first active region HV1 and exposing a portion of the dielectric material layer 120 above the first active region HV1, a mask pattern PR2 formed on the second active region HV2 and entirely covering the dielectric material layer 120 above the second active region HV2, and a mask pattern PR3 formed on the fourth active region MV and entirely covering the dielectric layer 130 above the fourth active region MV. Next, the portion of the dielectric material layer 120 on the first active region HV1 that is exposed by the mask layer is removed, so as to form a dielectric material layer 120a including the first recess r1.

In some embodiments, the mask layer exposes the dielectric layer 130 on the third active region LV, and therefore the dielectric layer 130 formed on the third active region LV is removed as well in the step of forming the first recess r1 in the dielectric material layer 120 on the first active region HV1.

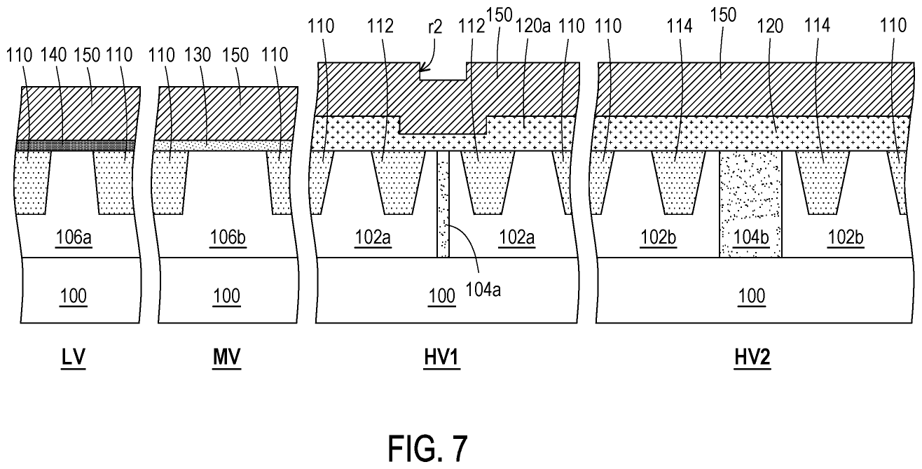

After that, referring to FIG. 6 and FIG. 7, the mask layer is removed and a dielectric layer 140 is formed on the third active region LV. In some embodiments, the dielectric layer 140 may include materials suitable for the gate dielectric layers, such as silicon oxide. Then, a gate material layer 150 is formed on the dielectric layer 140, the dielectric layer 130, the dielectric material layer 120a and the dielectric material layer 120. The gate material layer 150 may include materials suitable for the gate electrodes such as polycrystalline silicon. In some embodiments, the gate material layer 150 fills into the first recess r1, so that a top surface of the gate material layer 150 in the first active region HV1 includes a second recess r2 above the first recess r1 and being recessed toward the substrate 100.

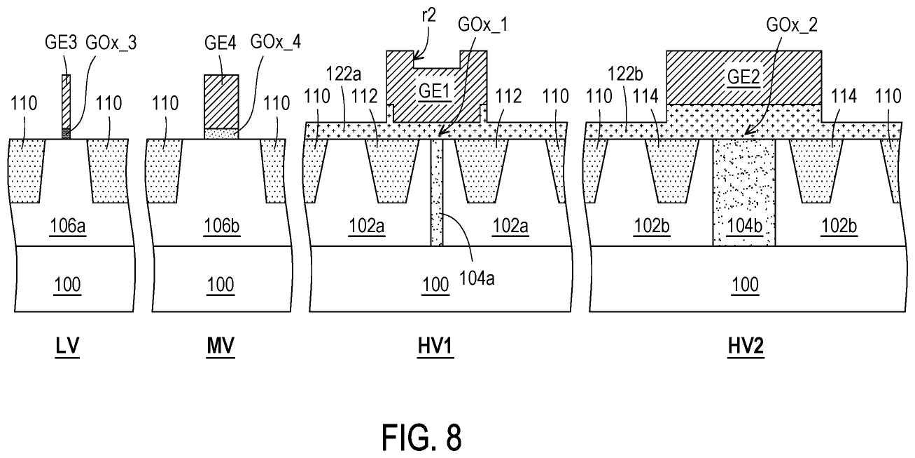

Then, referring to FIG. 7 and FIG. 8, the gate material layer 150 and the dielectric layer 140, the dielectric layer 130, the dielectric material layer 120a and the dielectric material layer 120 below the gate material layer 150 are patterned, such that a first gate electrode GE1 and a first gate dielectric layer GOx_1 included in a dielectric layer 122a and disposed between the first gate electrode GE1 and the substrate 100 are formed on the first active region HV1; a second gate electrode GE2 and a second gate dielectric layer GOx_2 included in a dielectric layer 122b and disposed between the substrate 100 and the second gate electrode GE2 are formed on the second active region HV2; a third gate electrode GE3 and a third gate dielectric layer GOx_3 disposed between the substrate 100 and the third gate electrode GE3 are formed on the third active region LV; and a fourth gate electrode GE4 and a fourth gate dielectric layer GOx_4 disposed between the substrate 100 and the fourth gate electrode GE4 are formed on the fourth active region MV.

In some embodiments, a top surface of the first gate electrode GE1 includes the second recess r2 above the first recess r1 and being recessed toward the substrate 100. In some embodiments, the top surface of the first gate electrode GE1 in a region other than the second recess r2 is formed at a level height identical to a top surface of the second gate electrode GE2.

In some embodiments, the first gate dielectric layer GOx_1 includes a first portion in contact with the substrate 100 and a second portion protruding from the first portion in the vertical direction, wherein a thickness (e.g., thickness t1 shown in FIG. 10) of the first portion in the vertical direction is smaller than a thickness (e.g., thickness t2 shown in FIG. 10) of the second gate dielectric layer GOx_2 in the vertical direction, and a top surface of the second portion is formed at a level height identical to a top surface of the second gate dielectric layer GOx_2. As such, the semiconductor device is capable of integrating the power devices and/or the logic devices (e.g., the first and second elements) having different operating voltages in the case where the stability of the manufacturing processes are good and the device performance of the first element (corresponding to a device formed on the first active region HV1) or the second element (corresponding to a device formed on the second active region HV2) is not sacrificed as well.

In some embodiments, a height of the second portion of the first gate dielectric layer GOx_1 protruding from the first portion is equal to a thickness of the dielectric layer 130 and/or a thickness of the dielectric layer 140. Namely, the height of the second portion of the first gate dielectric layer GOx_1 may be controlled by the thickness of the dielectric layer 130 and/or the thickness of the dielectric layer 140.

In some embodiments, the dielectric layer 122a covers the regions defined by the element isolation structure 110 and the first isolation structure 112 and extends onto the element isolation structure 110. The dielectric layer 122b covers the regions defined by the element isolation structure 110 and the second isolation structure 114 and extends onto the element isolation structure 110.

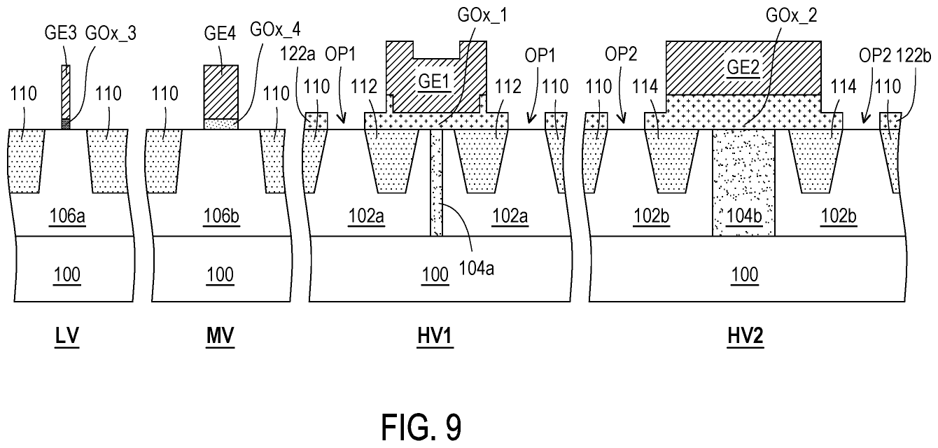

After that, referring to FIG. 9, first openings OP1 and second openings OP2 are formed in the dielectric layer 122a and the dielectric layer 122b, respectively. The first openings OP1 expose the regions defined by the element isolation structure 110 and the first isolation structure 112. The second openings OP2 expose the regions defined by the element isolation structure 110 and the second isolation structure 114.

Then, referring to FIG. 9 and FIG. 10, first source/drains SD1 are formed in the regions defined by the element isolation structure 110 and the first isolation structure 112 through the first openings OP1, and second source/drains SD2 are formed in the regions defined by the element isolation structure 110 and the second isolation structure 114 through the second openings OP2.

In some embodiments, in the step of forming the first source/drains SD1 and the second source/drains SD2, third source/drains SD3 are also formed in regions of the third well 106a that are defined by a third gate structure GS3 and the element isolation structure 110, and fourth source/drains SD4 are also formed in regions of the fourth well 106b that are defined by a fourth gate structure GS4 and the element isolation structure 110. In some embodiments, the first source/drains SD1, the second source/drains SD2, the third source/drains SD3, and the fourth source/drains SD4 may each include silicide such as tungsten silicide, titanium silicide, cobalt silicide, zirconium silicide, platinum silicide, molybdenum silicide, copper silicide or nickel silicide, but the present invention is not limited thereto.

Next, referring to FIG. 10, first gate spacers SW1 and second gate spacers SW2 are formed on sidewalls of the first gate electrode GEL and sidewalls of the second gate electrode GE2, respectively, and third gate spacers SW3 and fourth gate spacers SW4 are formed on sidewalls of the third gate electrode GE3 and sidewalls of the fourth gate electrode GE4, respectively. In some embodiments, the first gate spacers SW1, the second gate spacers SW2, the third gate spacers SW3, and the fourth gate spacers SW4 may each include silicon oxide, silicon nitride, or a combination thereof.

In some embodiments, the second portion of the first gate dielectric layer GOx_1 is disposed between the first gate electrode GE1 and the first gate spacers SW1 in the horizontal direction. In some embodiments, the third gate spacers SW3 are in contact with the substrate. In some embodiments, the fourth gate spacers SW4 are in contact with the substrate 100. In some embodiments, the first gate spacers SW1 are in contact with the dielectric layer 122a and spaced apart from the first isolation structure 112 by the dielectric layer 122a in the vertical direction. In some embodiments, the second portion of the first gate dielectric layer GOx_1 overlaps the first isolation structure 112 in the vertical direction. In some embodiments, the second gate spacers SW2 are in contact with the dielectric layer 122b and spaced apart from the second isolation structure 114 by the dielectric layer 122b in the vertical direction.

Hereinafter, the semiconductor structure 10 will be illustrated with reference to FIG. 10, but the method of forming the semiconductor structure 10 of the present invention is not limited thereto.

The semiconductor device 10 may include a substrate 100, a first element, and a second element. The substrate 100 includes a first active region HV1 and a second active region HV2 defined by an element isolation structure 110. The first element is disposed in the first active region HV1 and includes a first gate structure GS1. The first gate structure GS1 includes a first gate electrode GE1 and a first gate dielectric layer GOx_1 disposed between the substrate 100 and the first gate electrode GE1. The second element is disposed in the second active region HV2 and includes a second gate structure GS2. The second gate structure GS2 includes a second gate electrode GE2 and a second gate dielectric layer GOx_2 disposed between the substrate 100 and the second gate electrode GE2. The first gate dielectric layer GOx_1 includes a first portion in contact with the substrate 100 and a second portion protruding from the first portion in the vertical direction. A thickness (e.g., thickness t1) of the first portion in the vertical direction is smaller than a thickness (e.g., thickness t2) of the second gate dielectric layer GOx_2 in the vertical direction, and a top surface of the second portion is at a level height identical to a top surface of the second gate dielectric layer GOx_2.

In some embodiments, a top surface of the first gate electrode GE1 includes a recess (e.g., second recess r2) recessed toward the substrate 100. In some embodiments, the top surface of the first gate electrode GE1 in a region other than the recess (e.g., second recess r2) is at a level height identical to a top surface of the second gate electrode GE2.

In some embodiments, a horizontal area of the second element in the second active region HV2 is greater than a horizontal area of the first element in the first active region HV1.

In some embodiments, the first element includes a first isolation structure 112 disposed in the first active region HV1. The first isolation structure 112 defines regions with the element isolation structure 110 where first source/drains SD1 of the first element are disposed and defines a region under the first gate structure GS1 where a first doped region 104a of the first element is disposed. The second portion of the first gate dielectric layer GOx_1 overlaps the first isolation structure 112 in the vertical direction. In some embodiments, the first element includes first gate spacers SW1 disposed on sidewalls of the first gate electrode GE1. The second portion of the first gate dielectric layer GOx_1 is disposed between the first gate electrode GE1 and the first gate spacer SW1 in the horizontal direction.

In some embodiments, the semiconductor device 10 further includes a third element disposed in a third active region LV defined by the element isolation structure 110 and different from the first active region HV1 and the second active region HV2 and including a third gate structure GS3. The third gate structure GS3 includes a third gate electrode GE3, a third gate dielectric layer GOx_3 disposed between the substrate 100 and the third gate electrode GE3, and third gate spacers SW3 disposed on sidewalls of the third gate electrode GE3, wherein the third gate spacers SW3 are in contact with the substrate 100. In some embodiments, a horizontal area of the third element is smaller than a horizontal area of the first element and a horizontal area of the second element.

In some embodiments, the second element includes a second isolation structure 114 disposed in the second active region HV2. The second isolation structure 114 defines regions with the element isolation structure 110 where second source/drains SD2 of the second element are disposed and defines a region under the second gate structure GS2 where a second doped region 104b of the second element is disposed. A width of the second doped region 104b in the horizontal direction is greater than a width of the first doped region 104a in the horizontal direction.

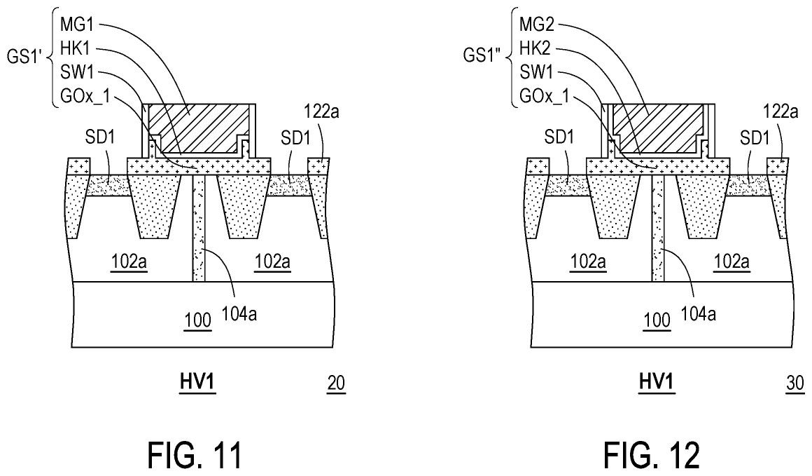

FIG. 11 is a schematic cross-section view illustrating a first element in an embodiment of the invention. A first element of a semiconductor device 20 shown in FIG. 11 is similar to the first element of the semiconductor device 10 shown in FIG. 10. The main difference therebetween is that the first gate structure GS1′ includes a high dielectric constant layer HK1 and a metal gate MG1. Other identical or similar components/layers/patterns are denoted by the same or similar reference numerals, which are not repeated herein.

Referring to FIG. 11, in the first active region HV1 of the semiconductor device 20, the first gate structure GS1′ of the first element includes a high dielectric constant layer HK1 and a metal gate MG1. The high dielectric constant layer HK1 is formed on the first gate dielectric layer GOx_1, and the metal gate MG1 is formed on the high dielectric constant layer HK1. In this embodiment, the metal gate MG1 includes portions in contact with the first gate spacers SW1. In some embodiments, the high dielectric constant layer HK1 may include dielectric

materials having high dielectric constants. For example, the dielectric materials having high dielectric constants may be materials having dielectric constants higher than that of silicon oxide (about 3.9). In some embodiments, the high dielectric constant layer HK1 may include HfO₂, TiO₂, HfZrO, Ta₂O₃, HfSiO₄, ZrO₂, ZrSiO₂, LaO, AlO, ZrO, TiO, Ta₂O₅, Y₂O₃, BaZrO, HfZrO, HfLaO, HfSiO, LaSiO, AlSiO, HfTaO, HTIO, Al₂O₃, Si₃N₄, SiON or combinations thereof.

In some embodiments, the metal gate MG1 may include tantalum nitride (TaN), nickel silicon (NiSi), cobalt silicon (CoSi), molybdenum (Mo), copper (Cu), tungsten (W), aluminum (Al), cobalt (Co), zirconium (Zr), platinum (Pt) or other suitable materials.

FIG. 12 is a schematic cross-section view illustrating a first element in another embodiment of the invention. A first element of a semiconductor device 30 shown in FIG. 12 is similar to the first element of the semiconductor device 20 shown in FIG. 11. The main difference therebetween is that the high dielectric constant layer HK2 in the first gate structure GS1″ separates the metal gate MG2 from the first gate spacers SW1. Other identical or similar components/layers/patterns are denoted by the same or similar reference numerals, which are not repeated herein.

Based on the above, in the aforementioned semiconductor device and method of forming the same, the first gate dielectric layer is designed to include the first portion in contact with the substrate and having the thickness smaller than the thickness of the second gate dielectric layer of the second element and the second portion protruding from the first portion and having the top surface at the level height identical to the top surface of the second gate dielectric layer. As such, the semiconductor device is capable of integrating the power devices and/or the logic devices (e.g., the first and second elements) having different operating voltages under the condition where the stability of the manufacturing processes are good and the device performances are not sacrificed as well.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor device, comprising:
a substrate comprising a first active region and a second active region defined by an element isolation structure;
a first element disposed in the first active region and comprising a first gate structure, and the first gate structure comprising a first gate electrode and a first gate dielectric layer disposed between the substrate and the first gate electrode; and
a second element disposed in the second active region and comprising a second gate structure, and the second gate structure comprising a second gate electrode and a second gate dielectric layer disposed between the substrate and the second gate electrode,
wherein the first gate dielectric layer comprises a first portion in contact with the substrate and a second portion protruding from the first portion in a vertical direction, a thickness of the first portion in the vertical direction is smaller than a thickness of the second gate dielectric layer in the vertical direction, and a top surface of the second portion is at a level height identical to a top surface of the second gate dielectric layer.

2. The semiconductor device of claim 1, wherein a top surface of the first gate electrode comprises a recess recessed toward the substrate.

3. The semiconductor device of claim 2, wherein the top surface of the first gate electrode in a region other than the recess is at a level height identical to a top surface of the second gate electrode.

4. The semiconductor device of claim 1, wherein a horizontal area of the second element is greater than a horizontal area of the first element.

5. The semiconductor device of claim 1, wherein the first element comprises a first isolation structure disposed in the first active region, the first isolation structure defines regions with the element isolation structure where first source/drains of the first element are disposed and defines a region under the first gate structure where a first doped region of the first element is disposed, and
the second portion of the first gate dielectric layer overlaps the first isolation structure in the vertical direction.

6. The semiconductor device of claim 5, wherein the first element comprises a first gate spacer disposed on a sidewall of the first gate electrode, and the second portion of the first gate dielectric layer is disposed between the first gate electrode and the first gate spacer in a horizontal direction.

7. The semiconductor device of claim 6, wherein the second element comprises a second gate spacer disposed on a sidewall of the second gate electrode, and the first gate spacer and the second gate spacer are respectively disposed on the first isolation structure and on the second isolation structure.

8. The semiconductor device of claim 7, further comprising:
a third element disposed in a third active region defined by the element isolation structure and different from the first active region and the second active region, and comprising a third gate structure, wherein the third gate structure comprises a third gate electrode, a third gate dielectric layer disposed between the substrate and the third gate electrode, and a third gate spacer disposed on a sidewall of the third gate electrode, and
wherein the third gate spacer is in contact with the substrate.

9. The semiconductor device of claim 8, wherein a horizontal area of the third element is smaller than a horizontal area of the first element and a horizontal area of the second element.

10. The semiconductor device of claim 5, wherein the second element comprises a second isolation structure disposed in the second active region, the second isolation structure defines regions with the element isolation structure where second source/drains of the second element are disposed and defines a region under the second gate structure where a second doped region of the second element is disposed, and
a width of the second doped region in a horizontal direction is greater than a width of the first doped region in the horizontal direction.

11. A method of forming a semiconductor device, comprising:
forming an element isolation structure defining a first active region and a second active region in a substrate;
forming a dielectric material layer on the first active region and the second active region of the substrate;
patterning a dielectric material layer on the first active region to form a first recess in the dielectric material layer on the first active region;
forming a gate material layer on the dielectric material layer; and
patterning the gate material layer and the dielectric material layer to form a first gate electrode and a first gate dielectric layer disposed between the substrate and the first gate electrode on the first active region and to form a second gate electrode and a second gate dielectric layer disposed between the substrate and the second gate electrode on the second active region,
wherein the first gate dielectric layer comprises a first portion in contact with the substrate and a second portion protruding from the first portion in a vertical direction, a thickness of the first portion in the vertical direction is smaller than a thickness of the second gate dielectric layer in the vertical direction, and a top surface of the second portion is formed at a level height identical to a top surface of the second gate dielectric layer.

12. The method of claim 11, further comprising:
forming a first gate spacer and a second gate spacer on a sidewall of the first gate electrode and a sidewall of the second gate electrode, respectively, and
wherein the second portion of the first gate dielectric layer is disposed between the first gate electrode and the first gate spacer in a horizontal direction.

13. The method of claim 11, wherein a top surface of the first gate electrode comprises a second recess above the first recess and being recessed toward the substrate.

14. The method of claim 13, wherein the top surface of the first gate electrode in a region other than the second recess is formed at a level height identical to a top surface of the second gate electrode.

15. The method of claim 12, further comprising:
forming a first isolation structure in the first active region to define regions with the element isolation structure where first source/drains are formed and a region under the first gate structure where a first doped region is formed,
wherein the second portion of the first gate dielectric layer overlaps the first isolation structure in the vertical direction.

16. The method of claim 15, further comprising:
forming a second isolation structure in the second active region to define regions with the element isolation structure where second source/drains are formed and a region under the second gate structure where a second doped region is formed,
wherein a width of the second doped region in the horizontal direction is greater than a width of the first doped region in the horizontal direction.

17. The method of claim 12, wherein the element isolation structure defines a third active region in the substrate, and in a step of forming the first recess in the dielectric material layer on the first active region, a dielectric layer on the third active region is removed as well.

18. The method of claim 17, wherein:
in a step of patterning the gate material layer and the dielectric material layer, a third gate electrode and a third gate dielectric layer disposed between the substrate and the third gate electrode are formed in the third active region; and
in a step of forming the first gate spacer and the second gate spacer, a third gate spacer is formed on a sidewall of the third gate electrode,
and the third gate spacer is in contact with the substrate.
